(19) United States
(12) Patent Application Publication
(10) Pub. No.: US 2013/0284992 A1
(43) Pub. Date: Oct. 31, 2013

(54) OPENING ASSEMBLY FOR INTERGRATED CIRCUIT SOCKET

(71) Applicants: Hong Fu Jin Precision Industry (ShenZhen) Co., Ltd., (US); HON HAI PRECISION INDUSTRY CO., LTD., New Taipei (TW)

(72) Inventor: WEI-MIN HE, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/859,545

(22) Filed: Apr. 9, 2013

(30) Foreign Application Priority Data
Apr. 25, 2012 (CN) 201210123631.3

(51) Int. Cl. H01L 23/00

(52) U.S. Cl. CPC H01L 23/564
USPC 254/133 R

(57) ABSTRACT

An opening assembly for opening an IC socket includes a supporting member and an opening member. The IC socket comprises a main body and two covers engaging with the main body. The supporting member resists against one of the covers by a first external force pushing the supporting member toward the main body. The opening member is slidably assembled to the supporting member. The supporting member is configured for pulling the other one of the covers away from the main body by a second external force opposite to the first external force. The opening member and the supporting member cooperatively open the other one of the covers.

### BACKGROUND

1. Technical Field

The disclosure generally relates to opening assemblies, and particularly to an opening assembly for opening an integrated circuit (IC) socket.

2. Description of Related Art

To conveniently update or burn programs of an IC such as a Basic Input Output System (BIOS) IC, an IC socket is commonly used to hold the IC. The IC socket usually includes a main body and two movable covers tightly engaging with main body to package the IC socket. However, because of a limitation of a volume of the IC socket, the IC socket has relative small or weak contacting points with a PCB. While opening the covers, wires routing of the PCB may be damaged due to improper operation. In addition, it is difficult and time-consuming to manually open the IC socket.

Therefore, there is room for improvement within the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the disclosure.

FIG. 1 is a schematic view of an opening assembly for opening an IC socket when the IC socket is opened, according to an exemplary embodiment of the disclosure

FIG. 2 is a disassembled view of the opening assembly of FIG. 1, according to an exemplary embodiment of the disclosure.

FIG. 3 is an assembled view of the opening assembly of FIG. 1, according to an exemplary embodiment of the disclosure.

FIG. 4 is similar to FIG. 1, but showing the IC socket closed.

### DETAILED DESCRIPTION

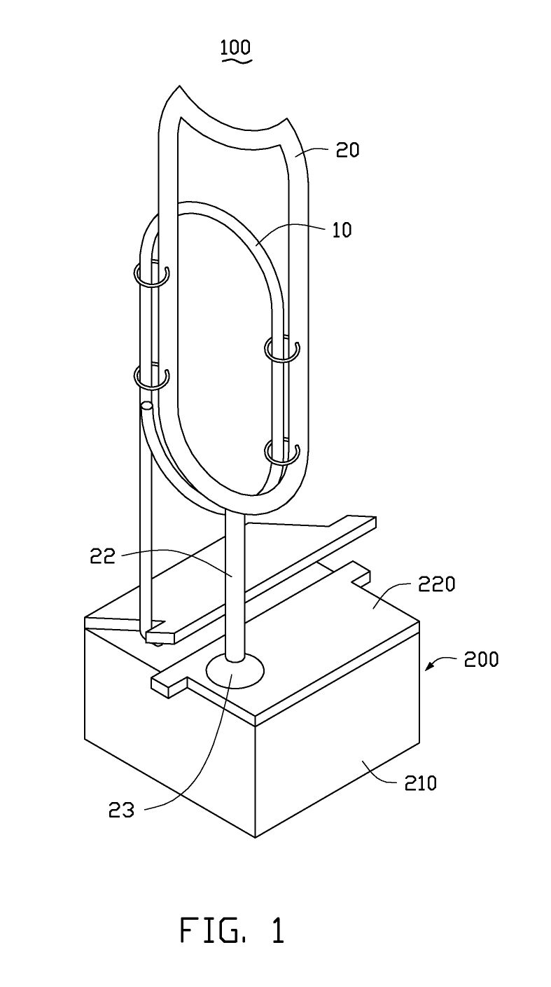

FIG. 1 is a schematic view of an opening assembly 100 for opening an IC socket 200, according to an exemplary embodiment of the disclosure. The IC socket 200 includes a main body 210 and two movable covers 220 engaging with the main body 210 to package an IC. The open assembly 100 includes an opening member 10 and a supporting member 20. The opening member 10 is slidably assembled to the supporting member 20.

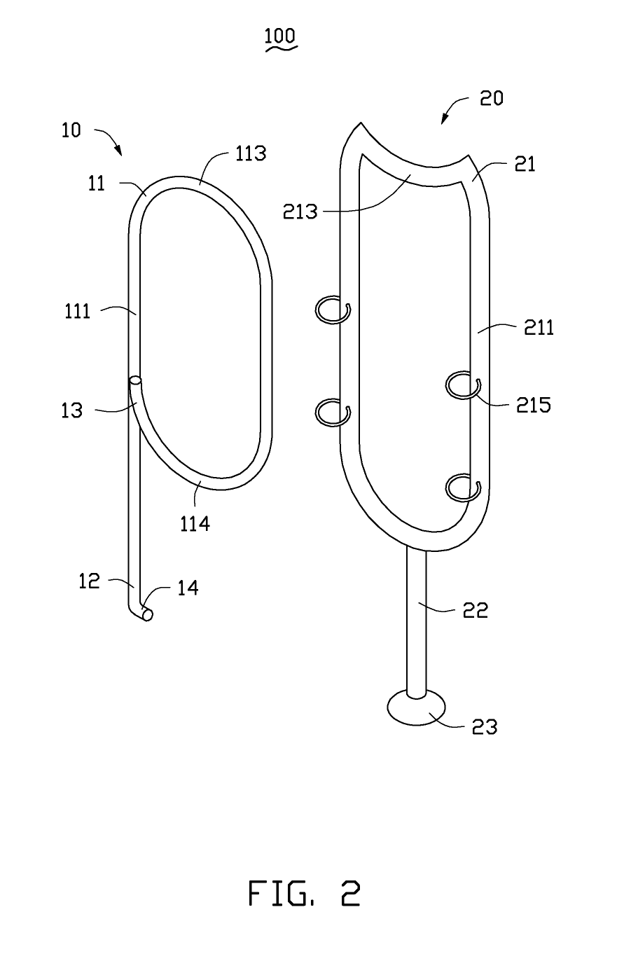

Referring to FIG. 2, the opening member 10 is substantially a curved metal pole including a sliding portion 11 and a hook 14. The sliding portion 11 is substantially an ellipse-shaped ring bent from a first end 13 of the opening member 10. the sliding portion 11 includes two parallel sliding poles 111, a pulling handle 113, and a stopper 114. The pulling handle 113 is substantially arc-shaped and connects to two ends of the sliding poles 111. The pulling handle 113 is configured for a user to pull the opening member 10. The stopper 114 is substantially arc-shaped and bent from the first end 13 opposite to the pulling handle 113. The hook 14 is bent from a second end 12 of the opening member 10.

The supporting member 20 includes a supporting bracket 21, a fixing pole 22 and a base 23. The supporting bracket 21 includes two opposite supporting poles 211 corresponding to the sliding poles 11 and a pushing handle 213 connected to the supporting poles 211. The pulling handle 213 is configured for a user to pull the supporting member 20. At least one pair of rings 215 are correspondingly secured to the two supporting poles 211. Two ends of the fixing pole 22 are correspondingly secured to the base 23 and a middle portion of the supporting bracket 21. The base 23 is configured to position on one of the cover 220.

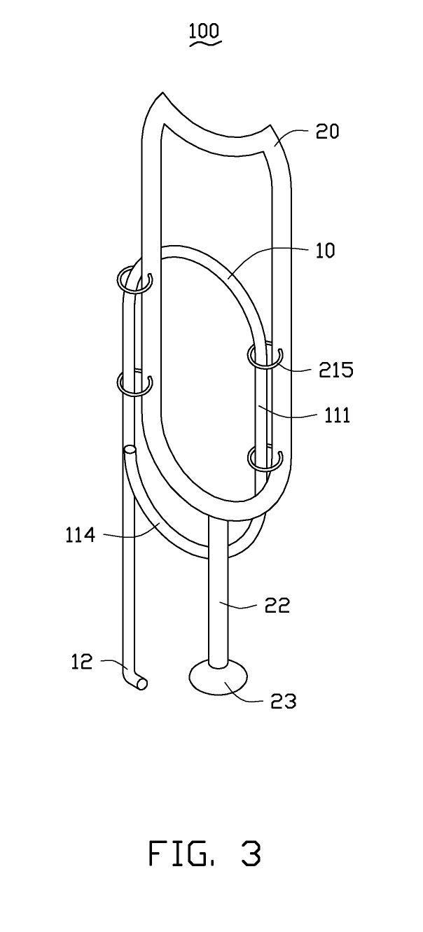

Referring to FIG. 3, to assemble the opening assembly 100, the first end 13 of the opening member 10 extends through the rings 215 with the rings 215 sleeved around each sliding pole 111. Thus, the sliding poles 11 can slide relative to the supporting poles 211 along the rings 215 and the opening member 10 is slidably assembled to the supporting member 20. In addition, the opening member 10 can be prevented from separating from the supporting member 215 with the stopper 114 abutting on the rings 215

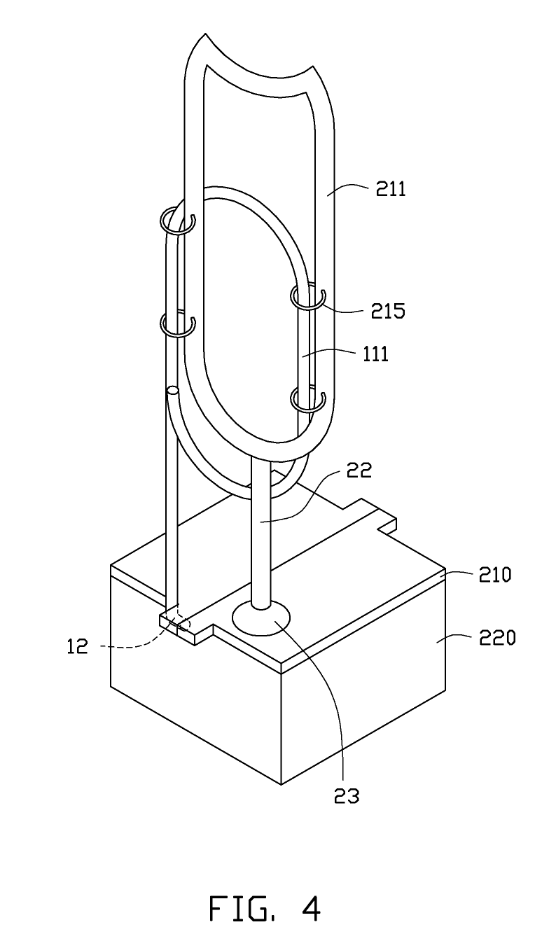

Also referring to FIG. 4, to open the IC socket 200, the base 23 is positioned on one of the covers 220 and the hook 14 is hooked at an edge of the other one of the covers 220. The base 23 resists against one of cover 220 by a first external force pushing the cover 220 toward the main body 210. The hook 14 pulls the other one of the covers 210 far away from the main body 210 by a second external force opposite the first external force. Therefore, the sliding poles 111 slide relative to the supporting member 20 until the other one of the covers 220 is opened (as shown in FIG. 1). The one of the covers 220 resisted by the base 23 can be also opened in this way with the base 23 positioned on an inner portion (not shown) of the main body 210 corresponding to the opened cover 220 and the hook 14 pulled the closed cover 220.

The structure of the opening assembly 100 is simple, and the volume of the opening assembly 100 is small. The covers 220 can be easily and conveniently opened by cooperatively operating the supporting member 20 and the opening member 10 without damaging other components such as a PCB connecting to the IC sockets 200.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An opening assembly for opening an integrated circuit (IC) socket, the IC socket comprising a main body and two covers engaging with the main body, the opening assembly comprising:
a supporting member resisting against one of the covers by a first external force pushing the supporting member toward the main body; and
an opening member slidably assembled to the supporting member, the supporting member for pulling the other one of the covers away from the main body by a second external force opposite to the first external force, the opening member and the supporting member cooperatively opening the other one of the covers.

2. The opening assembly of claim 1, wherein the opening member comprises a sliding portion bent from a first end of the opening member and a hook bent from a opposite second end of the opening member, the sliding portion is slidably assembled to the supporting member, the hook hooks an edge of the other one of the covers.

3. The opening assembly of claim 1, wherein the sliding portion comprises two parallel sliding poles; the supporting member comprises a supporting bracket, and a base, the supporting bracket comprises two supporting poles corresponding to the sliding poles, and at least one pair of rings, the at least one pair of rings are secured to the supporting poles; each ring is sleeved around one of the sliding poles.

4. The opening assembly of claim 1, wherein the sliding portion further comprises a pulling handle connecting to the sliding poles and configured for a user to pull the opening member.

5. The opening assembly of claim 1, wherein the sliding portion further comprises a stopper bent from the first end of the opening member to prevent the opening member from separating from the supporting member.

6. The opening assembly of claim 1, wherein the supporting member further comprises a pushing handle connecting to the supporting poles and configured for a user to push the supporting member.

7. An opening assembly comprising:
a supporting member; and
an opening member, the opening member comprising a sliding portion bent from a first end of the opening member and a hook bent from a second end of the opening member; the sliding portion slidably assembled to the supporting member.

8. The opening assembly of claim 7, wherein the sliding portion comprises two parallel sliding poles; the supporting member comprises a supporting bracket, and a base, the supporting bracket comprises two supporting poles corresponding to the sliding poles, and at least one pair of rings, the at least one pair of rings are secured to the supporting poles; each ring is sleeved around one of the sliding poles.

9. The opening assembly of claim 7, wherein the sliding portion further comprises a pulling handle connecting to the sliding poles and configured for a user to pull the opening member.

10. The opening assembly of claim 7, wherein the sliding portion further comprises a stopper bent from the first end of the opening member to prevent the opening member from separating from the supporting member.

11. The opening assembly of claim 7, wherein the supporting member further comprises a pushing handle connecting to the supporting poles and configured for a user to push the supporting member.
